(19) United States
(12) Patent Application Publication
(10) Pub. No.: US 2024/0120410 A1
(43) Pub. Date: Apr. 11, 2024

(54) SEMICONDUCTOR STRUCTURE AND METHOD OF FORMING THEREOF

(71) Applicant: Hon Young Semiconductor Corporation, Hsinchu City (TW)

(72) Inventors: Yu-Tsu LEE, Hsinchu City (TW); Yan-Ru CHEN, Hsinchu City (TW); Chao-Yi CHANG, Hsinchu City (TW); Kuang-Hao CHIANG, Hsinchu City (TW)

(21) Appl. No.: 18/170,523

(22) Filed: Feb. 16, 2023

(30) Foreign Application Priority Data
Oct. 11, 2022 (TW) 111138460

(51) Int. Cl. H01L 29/66; H01L 29/06; H01L 29/16; H01L 29/808

(52) U.S. Cl. CPC H01L 29/66909; H01L 29/0619; H01L 29/1608; H01L 29/8083

(57) ABSTRACT

A semiconductor structure includes a semiconductor epitaxial layer, a first semiconductor well, a second semiconductor well, a source doped region, a gate structure and a drain structure. The semiconductor epitaxial layer includes a first side and a second side opposite to the first side. The first semiconductor well is located on the first side of the semiconductor epitaxial layer. The second semiconductor well is located on the second side of the semiconductor epitaxial layer. The source doped region is located in the first semiconductor well. The gate structure overlaps the first semiconductor well and the source doped region on the first side of the semiconductor epitaxial layer. The drain structure includes a semiconductor substrate. The second side of the semiconductor epitaxial layer outside the second semiconductor well includes a connecting surface. The connecting surface of the semiconductor epitaxial layer is connected to the semiconductor substrate.

### RELATED APPLICATIONS

This application claims priority to Taiwan Application Serial Number 111138460, filed Oct. 11, 2022, which is herein incorporated by reference in its entirety.

### BACKGROUND

### Field of Invention

The present disclosure relates to semiconductor structure and method of forming semiconductor structures.

### Description of Related Art

In the field of semiconductor technology, vertical junction field transistors can be used as power components. However, in an integrated circuit structure, the transistors may be subjected to bias voltage application from different locations, resulting in unintended current paths and generations of leakage currents. Therefore, how to increase the voltage resistance of transistors is an issue that technicians in the field would like to address. However, in some solutions to improve the voltage resistance of transistors, additional components are often used, which not only increases the overall area of the transistor but also increases the difficulty and cost of the overall manufacturing process.

Therefore, how to provide a solution that can effectively improve the voltage resistance of transistors without taking up additional working area is one of the problems those in the industry want to solve.

### SUMMARY

An aspect of the present disclosure is related to a semiconductor structure.

According to one or more embodiments of the present disclosure, a semiconductor structure includes a semiconductor epitaxial layer, a first semiconductor well, a second semiconductor well, a source doped region, a gate structure and a drain structure. The epitaxial layer includes a first side and a second side opposite to the first side. The first semiconductor well is located on the first side of the semiconductor epitaxial layer. The second semiconductor well is located on the second side of the semiconductor epitaxial layer. The source doped region is located in the first semiconductor well. The gate structure is located on the first side of the semiconductor epitaxial layer and overlaps the first semiconductor well and the source doped region. The drain structure includes a semiconductor substrate. The second side of the semiconductor epitaxial layer includes a connecting surface located on the second side of the semiconductor epitaxial layer and outside the second semiconductor well. The connecting surface is connected to the semiconductor substrate.

In one or more embodiments of the present disclosure, the drain structure further includes a drain doped region and a conductive layer. The drain doped region extends from the second side of the semiconductor epitaxial layer into the semiconductor epitaxial layer. The conductive layer connects the drain doped region to the semiconductor substrate.

In some embodiments, the drain doped region extends into the second semiconductor well and extends to the second side of the semiconductor epitaxial layer outside the second semiconductor well.

In one or more embodiments of the present disclosure, the semiconductor structure further includes a source electrode and a drain electrode. The source electrode is located on the first side of the semiconductor epitaxial layer, overlaps the source doped region and is separated from the gate structure. The drain electrode is located below the semiconductor substrate of the drain structure. The semiconductor substrate is located between the drain electrode and the semiconductor epitaxial layer.

In one or more embodiments of the present disclosure, the semiconductor structure further includes a third semiconductor well and another source doped region located in the third semiconductor well and covered by the gate structure. The third semiconductor well is located on the first side of the semiconductor epitaxial layer.

In one or more embodiments of the present disclosure, the semiconductor structure further includes a guard ring well and a third semiconductor well. The guard ring well extends from the first side of the semiconductor epitaxial layer into the semiconductor epitaxial layer and surrounds the first semiconductor well. The third semiconductor well extends from the second side of the semiconductor epitaxial layer into the semiconductor epitaxial layer and surrounds the second semiconductor well.

An aspect of the present disclosure is related to a semiconductor structure.

According to one or more embodiments of the present disclosure, a semiconductor structure includes a semiconductor epitaxial layer, a first semiconductor well, a second semiconductor well, a source doped region, a gate structure and a drain structure. The semiconductor epitaxial layer includes a first side and a second side opposite to the first side. The first semiconductor well is located on the first side of the semiconductor epitaxial layer. The second semiconductor well is located on the second side of the semiconductor epitaxial layer and aligned with the first semiconductor well. The source doped region is located in the first semiconductor well. The gate structure is located at the first side of the semiconductor epitaxial layer and overlaps the first semiconductor well and the source doped region. The drain structure includes a semiconductor substrate. The second side of the semiconductor epitaxial layer includes a connecting surface outside the second semiconductor well. The connecting surface is connected to the semiconductor substrate. Each of the source doped region, the semiconductor epitaxial layer and the semiconductor substrate has a first semiconductor type. Each of the first semiconductor well and the second semiconductor well has a second semiconductor type different from the first semiconductor type.

In one or more embodiments of the present disclosure, the drain structure further includes a drain doped region and a conductive layer. The drain doped region has a first semiconductor type and extends from the second side of the semiconductor epitaxial layer into the semiconductor epitaxial layer. The conductive layer connects the drain doped region to the semiconductor substrate.

In some embodiments, the drain doped region extends into the second semiconductor well.

In one or more embodiments of the present disclosure, the semiconductor structure further includes a source electrode and a drain electrode. The source electrode is located on the first side of the semiconductor epitaxial layer, overlaps the source doped region and is separated from the gate structure. The drain electrode is located below the semiconductor substrate of the drain structure. The semiconductor substrate is located between the drain electrode and the semiconductor epitaxial layer.

In one or more embodiments of the present disclosure, the semiconductor structure further includes a guard ring well and a third semiconductor well. The guard ring well extends from the first side of the semiconductor epitaxial layer into the semiconductor epitaxial layer and surrounds the first semiconductor well. The third semiconductor well extends from the second side of the semiconductor epitaxial layer into the semiconductor epitaxial layer and surrounds the second semiconductor well.

In one or more embodiments of the present disclosure, the gate structure includes an oxide layer and a gate electrode. The oxide layer is located on the first side of the semiconductor epitaxial layer and overlaps the source doped region. The gate electrode is located on the oxide layer.

In one or more embodiments of the present disclosure, the semiconductor substrate is a silicon carbide substrate.

An aspect of the present disclosure is related to a method of forming a semiconductor structure.

In one or more embodiments of the present disclosure, a method of forming a semiconductor structure includes a number of operations. A semiconductor epitaxial layer is formed on a first semiconductor substrate, wherein the semiconductor epitaxial layer comprises a first side and a second side opposite to the first side, the second side of the semiconductor epitaxial layer is connected to the first semiconductor substrate. A first semiconductor well is formed on the first side of the semiconductor epitaxial layer. A source doped region is formed in the first semiconductor well. A gate structure is formed, wherein the gate structure is located on the first side of the semiconductor epitaxial layer and overlaps the first semiconductor well and the source doped region. An adhesive layer is formed to cover the first side of the semiconductor epitaxial layer. The first side of the semiconductor epitaxial layer is fixed on a transfer substrate. The semiconductor epitaxial layer and the first semiconductor substrate are flipped by the transfer substrate. The first semiconductor substrate is removed to expose the second side of the semiconductor epitaxial layer. A second semiconductor well is formed on the second side of the semiconductor epitaxial layer. A drain structure is formed to cover the second side of the semiconductor epitaxial layer. The adhesive layer and the transfer substrate are removed after the drain structure is formed.

In one or more embodiments of the present disclosure, forming the drain structure forming the drain structure includes connecting a second semiconductor substrate to the second side of the semiconductor epitaxial layer; and forming a drain electrode below the second semiconductor substrate, wherein the second semiconductor substrate is located between the semiconductor epitaxial layer and the drain electrode.

In one or more embodiments of the present disclosure, forming the drain structure includes forming a drain doped region extending from the second side of the semiconductor epitaxial layer into the semiconductor epitaxial layer and the second semiconductor well after the second semiconductor well is formed and connecting a second semiconductor substrate to the drain doped region by a conductive layer.

In one or more embodiments of the present disclosure, the second semiconductor well is formed to be aligned with the first semiconductor well.

In one or more embodiments of the present disclosure, forming the gate structure includes forming an oxide layer overlapping the first side of the semiconductor epitaxial layer before the adhesive layer is formed or the transfer substrate is removed and forming a conductive layer over the oxide layer.

In one or more embodiments of the present disclosure, the method further includes forming a source electrode separated from the gate structure and overlapping the source doped region before the adhesive layer is formed or the transfer substrate is removed.

In one or more embodiments of the present disclosure, the first semiconductor substrate is a silicon carbide substrate, and the transfer substrate is a sapphire substrate.

In summary, by setting up a transfer substrate in the semiconductor processing operation, a required structure is formed by flexibly performing the semiconductor process on the front side and the back side of the semiconductor epitaxial layer, thus forming a doped region for increasing voltage resistance of the semiconductor epitaxial layer in the vertical transistor structure without occupying additional working area and avoiding the generation of unintended leakage currents.

It is to be understood that both the foregoing general description and the following detailed description are by examples, and are intended to provide further explanation of the disclosure as claimed.

### BRIEF DESCRIPTION OF THE DRAWINGS

The advantages of the present disclosure are to be understood by the following exemplary embodiments and with reference to the attached drawings. The illustrations of the drawings are merely exemplary embodiments and are not to be considered as limiting the scope of the disclosure.

FIG. 1 illustrates a schematic cross-sectional view of a semiconductor structure according to one or more embodiments of the present disclosure;

FIGS. 2-12 illustrate a plurality of schematic cross-sectional views of a plurality of intermediate operations forming a semiconductor structure according to one or more embodiments of the present disclosure;

FIGS. 13-16 illustrate a plurality of schematic cross-sectional views of a plurality of intermediate operations forming a semiconductor structure according to an embodiment of the present disclosure;

FIG. 17 illustrates a schematic cross-sectional view of a semiconductor structure according to one or more embodiments of the present disclosure;

FIG. 18 illustrates a schematic cross-sectional view of a semiconductor structure according to one or more embodiments of the present disclosure;

FIG. 19 illustrates a schematic cross-sectional view of the semiconductor structure according to one or more embodiments of the present disclosure; and

FIG. 20 illustrates a flowchart of a method of forming a semiconductor structure according to one or more embodiments of the present disclosure.

### DETAILED DESCRIPTION

Reference will now be made in detail to the embodiments of the present disclosure, examples of which are illustrated in the accompanying drawings. Wherever possible, the same reference numbers are used in the drawings and the description to refer to the same or like parts.

In addition, terms used in the specification and the claims generally have the usual meaning as each terms are used in the field, in the context of the disclosure and in the context of the particular content unless particularly specified. Some terms used to describe the disclosure are to be discussed below or elsewhere in the specification to provide additional guidance related to the description of the disclosure to specialists in the art.

Phrases “first,” “second,” etc., are solely used to separate the descriptions of elements or operations with same technical terms, not intended to be the meaning of order or to limit the disclosure.

Secondly, phrases “comprising,” “includes,” “provided,” and the like, used in the context are all open-ended terms, i.e. including but not limited to.

Further, in the context, “a” and “the” can be generally referred to one or more unless the context particularly requires. It will be further understood that phrases “comprising,” “includes,” “provided,” and the like, used in the context indicate the characterization, region, integer, step, operation, element and/or component it stated, but not exclude descriptions it stated or additional one or more other characterizations, regions, integers, steps, operations, elements, components and/or groups thereof.

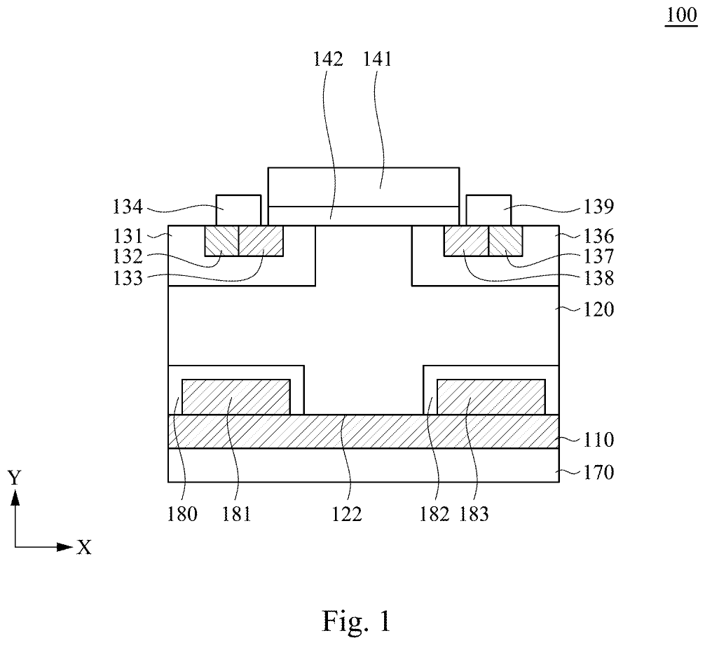

Reference is made to FIG. 1. FIG. 1 illustrates a schematic cross-sectional view of a semiconductor structure 100 according to one or more embodiments of the present disclosure.

As shown in FIG. 1, in one or more embodiments of the present disclosure, the semiconductor structure includes a substrate 110, a semiconductor epitaxial layer 120, an oxide layer 142, a conductive layer 141, an electrode 134, an electrode 139, and an electrode 170. Semiconductor doped wells 131, 136, 180 and 182 are formed over the semiconductor epitaxial layer 120. Doped regions 132 and 133 are formed in the well 131. Doped regions 137 and 138 are formed in the well 136. A doped region 181 is formed in the well 180. A doped region 183 is formed in the well 182.

In FIG. 1, the semiconductor structure 100 is a vertical transistor structure. In detail, the doped region 133 in the well 131 can be used as a source structure of the semiconductor structure 100, the conductive layer 141 and the oxide layer 142 form a gate of the semiconductor structure 100 and cover the doped region 132 and the substrate 110 can be used as a drain structure of the semiconductor structure 100. On the other hand, the doped region 137 in the well 136 can also be sued as a source structure of the semiconductor structure 100, the conductive layer 141 and the oxide layer 142 form the gate of the semiconductor structure 100 and cover the doped region 132 and the substrate 110 can be used as the drain structure of the semiconductor structure 100. The semiconductor structure 100 may be considered as two vertical transistors including a common gate structure (i.e., the gate structure formed by the conductive layer 141 and the oxide layer 142) and a common drain structure (i.e., the substrate 110).

In one or more embodiments of the present disclosure, the semiconductor epitaxial layer 120 has a first semiconductor type. The well 131 has a second semiconductor type that is different from the first semiconductor type. For example, but not limited to, the semiconductor epitaxial layer 120 has a first semiconductor type of n-doping and the well 131 has a second semiconductor type of p-doping. The doped region 132 has the second semiconductor type, and a doping concentration of the doped region 132 is greater than a doping concentration of the well 131. The doped region 132 may be considered to have a heavily p-type doping (p⁺-doping). The doped region 133 has a first semiconductor type and a doping concentration of the doped region 133 is greater than a doping concentration of the semiconducting epitaxial layer 120. The doped region 133 may be considered to have a heavily n-doped (n+-doping). The semiconductor substrate 110 has a great n⁺-doping concentration.

In FIG. 1, the oxide layer 142 overlaps directly onto the doped region 133 and the oxide layer 142 overlaps directly onto the exposed well 131 outside of the doped region 133. The conductive layer 141 located above the oxide layer 142 extends above the well 131 outside of the doped region 133. In this embodiment, the oxide layer 142 is used to insulate the conductive layer 141 from the doped region 133. In this embodiment, the oxide layer 142 is used to insulate the conductive layer 141 from the doped region 133. In some embodiments, the conductive layer 141 is, for example, a polycrystalline (poly) semiconductor material capable of being used as a gate electrode for a transistor to perform gate switching by applying different bias voltages. In some embodiments, the conductive layer 141 may be a gate metal layer.

In this embodiment, the doped region 133 of the source, the well 131, the semiconductor epitaxial layer 120 and the substrate 110 form an n-p-n structure. The oxide layer 142 and the conductive layer 141 used as the gate are located on the p-type well 131 of the n-p-n structure to control the movement of n-type carriers (electrons) from the doped region 133 through the well 131 to the semiconductor epitaxial layer 120. The carriers then move through the semiconductor epitaxial layer 120 to the substrate 110.

As shown in FIG. 1, the electrode 134 used as the source structure is provided above the doped region 133, and the electrode 170 as the drain structure is provided below the substrate 110. In some embodiments, the material of electrode 134 and electrode 170 can be selected as suitable conductive material to reduce an overall equivalent on-resistance of the transistor in the semiconductor structure 100.

On the other hand, in one or more embodiments of the present disclosure, the semiconductor epitaxial layer 120 has a first semiconductor type. The well 136 has a second semiconductor type that is different from the first semiconductor type. For example, but without limitation, in this embodiment, the semiconductor epitaxial layer 120 has a first semiconductor type of n-type doping (n-doping) and the well 136 has a second semiconductor type of p-type doping (p-doping). The doped region 137 has a second semiconductor type and a doping concentration of the doped region 137 is greater than a doping concentration of the well 136. The doped region 137 may be considered to have a heavily p+-type doping (p⁺-doping). The doped region 138 has a first semiconductor type and a doping concentration of the doped region 138 is greater than a doping concentration of the semiconducting epitaxial layer 120. The doped region 138 may be considered to have a heavily n-doping (n⁺-doping). The semiconductor epitaxial layer 120 has n-type doping. The semiconductor substrate 110 has a great concentration of heavily n⁺-doping.

Similarly, the doped region 138, the well 136, the semiconductor epitaxial layer 120 and the substrate 110 form an n-p-n structure. The carriers can then move from the semiconductor epitaxial layer 120 to the substrate 110 from the semiconductor epitaxial layer 120.

In this embodiment, the semiconductor epitaxial layer 120 can be considered as a drift layer for n-type carriers. The carriers can drift from the semiconductor epitaxial layer 120 to the substrate 110, which is used as the drain structure.

In this embodiment, the semiconductor structure 100 further includes a well 180 opposite the well 131 in the direction Y and the well 182 opposite the well 136 in the direction Y. In detail, the semiconductor epitaxial layer 120 includes a front side and a back side opposite to the front side in the direction Y. The semiconductor structure 100 further comprises an opposite front side and a back side in the direction Y. The well 131 and the well 136 are located on the front side of the epitaxial layer 120. The well 180 and the well 182 are located on the back side of the epitaxial layer 120. In other words, in direction X, the well 180 on the back side of the semiconductor epitaxial layer 120 is aligned with well 131 on the front side of the semiconductor epitaxial layer 120, and the well 182 on the back side of the semiconductor epitaxial layer 120 is aligned with the well 136 on the front side of the semiconductor epitaxial layer 120.

In FIG. 1, the doped region 181 extends from the back side of the epitaxial layer 120 into the well 180, and the doped region 183 extends from the back side of the epitaxial layer 120 into the well 182. The substrate 110 covers the back side of the epitaxial layer 120 to directly contact the doped regions 181 and 183. In addition, the epitaxial layer 120 includes a connecting surface outside the well 180 and the well 182, and the connecting surface of the epitaxial layer 120 is directly connected to the substrate 110.

In one or more embodiments of the present disclosure, the well 180 and the doped region 181 in the well 180 can be used as a withstand voltage structure to avoid a generation of unintended current paths. In detail, in this embodiment, the well 180 may have a second semiconductor type different from the first semiconductor type. For example, the first semiconductor type is p-type doping and the second semiconductor type is n-type doping. The doped region 181 within the well 180 may have a heavily doping of the first semiconductor type. In this embodiment, the doped region 181 has a heavily n⁺-doping. The well 180 and the doped region 181 form a PN junction and the p-type well 180 and the n-type doped region 181 are connected to the substrate 110 together. Therefore, it is difficult for the well 180 and the doped region 181 to have carriers to flow, so a possible current path is blocked at the well 180 and the doped region 181 to avoid leakage current.

Similarly, in one or more embodiments of the present disclosure, the well 182 and the doped region 183 in the well 182 can be used as a withstand voltage structure to avoid a generation of unintended current paths. In this embodiment, the well 182 may have a second semiconductor type different from the first semiconductor type. For example, the first semiconductor type is p-type doping and the second semiconductor type is n-type doping. The doped region 183 within the well 182 may have a heavily doping of the first semiconductor type. In this embodiment, the doped region 183 has a heavily n⁺-doping. The well 182 and the doped region 183 form a PN junction and the p-type well 182 and the n-type doped region 183 are connected to the substrate 110 together. Therefore, it is difficult for the well 182 and the doped region 183 to have carriers to flow, so a possible current path is blocked at the well 182 and the doped region 183 to avoid leakage current.

Accordingly, by forming the well 180, the doped region 181, the well 182 and the doped region 183 on the back side of the epitaxial layer 120 as withstand voltage structures, the generation of leakage current is avoided. At the same time, the withstand voltage structure formed on the back side of the epitaxial layer 120 would not occupy additional area on the front side of the semiconductor structure 100.

In this embodiment, as shown in FIG. 1, the well 180 is configured to be aligned with the well 131 and the well 182 is configured to be aligned with the well 136. The second side 122 of the epitaxial layer 120 further includes a connecting surface outside the well 180 and the well 182. The connecting surface is located between the well 180 and the well 182 and the connecting surface is directly connected to the substrate 110. The oxide layer 142 and the conductive layer 141 used as the gate structure can be aligned with the connecting surface outside the well 180 and the well 182 of the epitaxial layer. It will facilitate the flow of carriers to the substrate 110. In other words, it can also be considered that the arrangement of the well 180 and the well 182 restricts the current path so that carriers can flow from the connecting surface of epitaxial layer 120 to substrate 110 from second side 122 exposed outside the well 180 and the well 182.

In one or more embodiments of the present disclosure, the material of the semiconductor epitaxial layer 120 and the substrate 110 may be silicon carbide (SiC). In one or more embodiments, the semiconductor epitaxial layer 120 and the substrate 110 may include silicon or other suitable semiconductor materials.

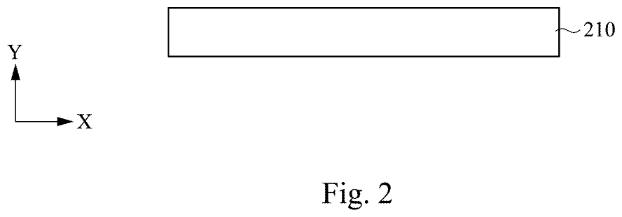

Reference is made to FIGS. 2-12 to further illustrate formation of the semiconductor structure. FIGS. 2-12 illustrate a plurality of schematic cross-sectional views of a plurality of intermediate operations forming a semiconductor structure 100 according to one or more embodiments of the present disclosure.

In FIG. 2, a semiconductor substrate 210 is provided. In some embodiments, the material of the substrate 210 is silicon carbide, for example. In some embodiments, the material of the substrate 210 can be other suitable semiconductor materials, which can be subsequently used to form the epitaxial layer 120 made of silicon carbide.

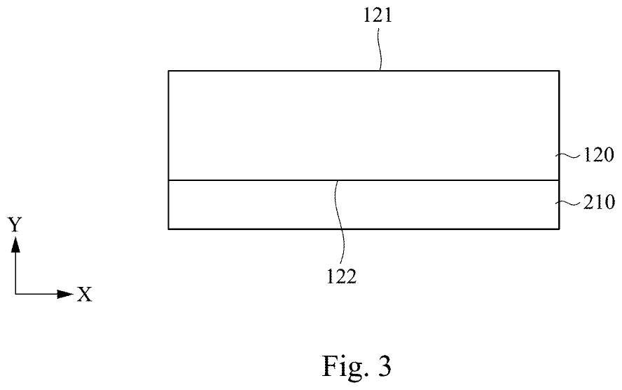

Following FIG. 2, in FIG. 3, a semiconductor epitaxial layer 120 is formed on the substrate 210. In the schematic cross-section view as illustrated in FIG. 3, the semiconductor epitaxial layer 120 includes a front side (i.e., the first side 121) and the back side (i.e., the second side) opposite to the front side in the direction Y. The second side 122 of the semiconductor epitaxial layer 120 is connected to the substrate 210.

As shown in FIG. 3, the second side 122 of the semiconductor epitaxial layer 120 is directly connected to a top surface of the substrate 210. In one or more embodiments, the semiconductor epitaxial layer 120 can be formed on the substrate 210 by a depositing process. In some embodiments, the depositing process includes physical vapor deposition (PVD), chemical vapor deposition (CVD), or atomic layer deposition (ALD).

In one or more embodiments of the present disclosure, the epitaxial layer 120 can has the first semiconductor type. For example, in this embodiment, the epitaxial layer 120 may be a silicon carbide semiconductor layer doped with n-type doping.

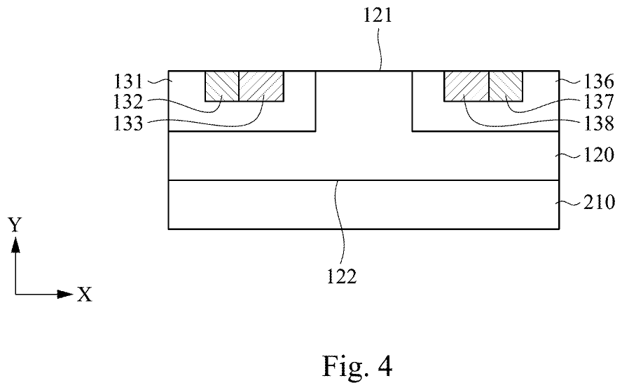

In FIG. 4, a well 131 and a well 136 are formed by doping the first side 121 of the epitaxial layer 120, a doped region 132 and a doped region 133 are then formed in the well 131 and a doped region 137 and a doped region 138 are formed in the well 136. The well 131 is formed on the first side 121 of the epitaxial layer 120 separately from the well 136 in the direction X.

The well 131 has a second semiconductor type different from the first semiconductor type of the semiconductor epitaxial layer 120. In this embodiment, the doping concentration of the doped region 132 is greater than the doping concentration of the well 131, and the doped region 132 has a heavily p+-doping. The doped regions 133 are of the first semiconductor type. In this embodiment, the doping concentration of the doped region 133 is greater than the doping concentration of the epitaxial layer 120, and the doped region 133 has a heavily n⁺-doping. The doped region 133 may be used as a source of a transistor structure.

Similarly, in FIG. 4, the well 136 has a second semiconductor type different from the first semiconductor type of the semiconductor epitaxial layer 120. In this embodiment, the well has p-type doping. After the well 136 is formed, a semiconductor doping process is further performed to form doped regions 137 and 138 in the well 136. In this embodiment, the doping concentration of the doped region 137 is greater than the doping concentration of the well 136, and the doped region 137 has a heavily p+-doping. The doped regions 138 are of the first semiconductor type. In this embodiment, the doping concentration of the doped region 138 is greater than the doping concentration of the epitaxial layer 120, and the doped region 138 has a heavily n⁺-doping. The doped region 138 may be used as a source of another transistor structure.

In one or more embodiments of the present disclosure, the well 131 and the well 136 can be formed in the same process, and then the doped regions 132 and 133 are formed in the well 131 and the doped region 137 and 138 are formed in the well 136.

The doped region 132 and the doped region 137 of the second semiconductor type can be used to surround the doped region 133 and the doped region 138 to avoid unintended current paths in the horizontal direction X. It ensures that the carriers from the doped region 133 and the doped region 138 can move into the semiconductor epitaxial layer 120.

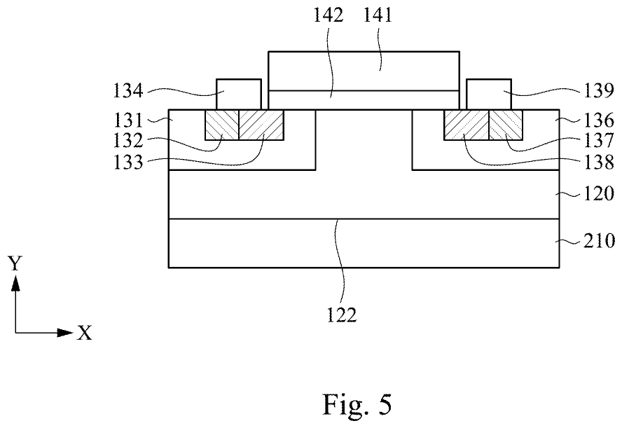

Following FIG. 4, in FIG. 5, a gate structure is formed on the first side of the epitaxial layer 120, wherein the gate structure includes an oxide layer 142 and a conductive layer 141. The oxide layer 142 is directly connected to the wells 131 and 136 and extends above the doped regions 133 and 138. Bias can be applied to the formed gate structure through the conductive layer to control the on/off switching of the vertical transistor structure channel.

Further, in FIG. 5, an electrode 134 is formed to overlap the doped regions 132 and 133, and an electrode 139 is formed to overlap the doped regions 137 and 138. As shown in FIG. 5, the conductive layer 141 and the oxide layer 142 of the gate structure are separated from the electrode 134 and the electrode 139 in the direction X. The electrode 134 and the electrode 139 are respectively connected to the doped region 133 and the doped region 138, which are used as sources of transistors, and the electrode 134 and the electrode 139 can be regarded as the source electrode connected to the sources of the transistors.

In some embodiments, the electrode 134 and the electrode 139 can be formed on the first side 121 of the epitaxial layer 120 after other components or structures are formed on the second side of the epitaxial layer 120.

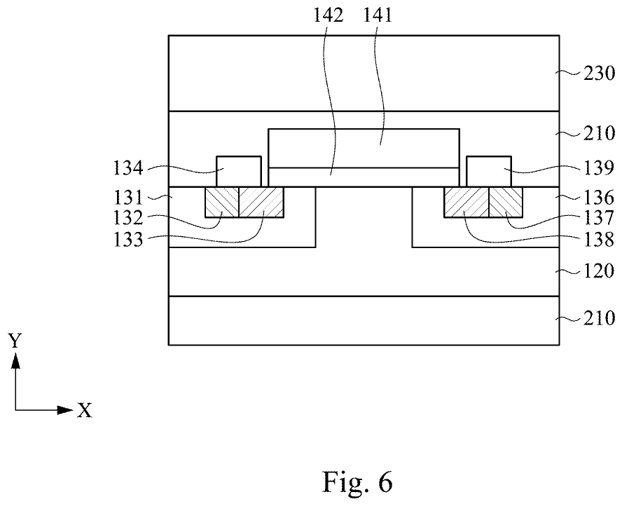

Reference is made to FIG. 6. In the schematic cross-section view as illustrated in FIG. 6, an adhesive layer 220 is formed on the first side 121 of the semiconductor epitaxial layer 120. In this embodiment, the well 131, the doped region 132, the doped region 133, the electrode 134, the gate structure including the conductive layer 141 and the oxide layer 142, the well 136, the doped region 137, the doped region 138 and the electrode 139 exposed from the first side 121 of the semiconductor epitaxial layer 120 are covered by the adhesive layer 220. In some embodiments, the adhesive layer 220 may include a colloid sufficient to withstand a certain temperature. For specific characteristics of the adhesive layer 220, please refer to the subsequent discussion.

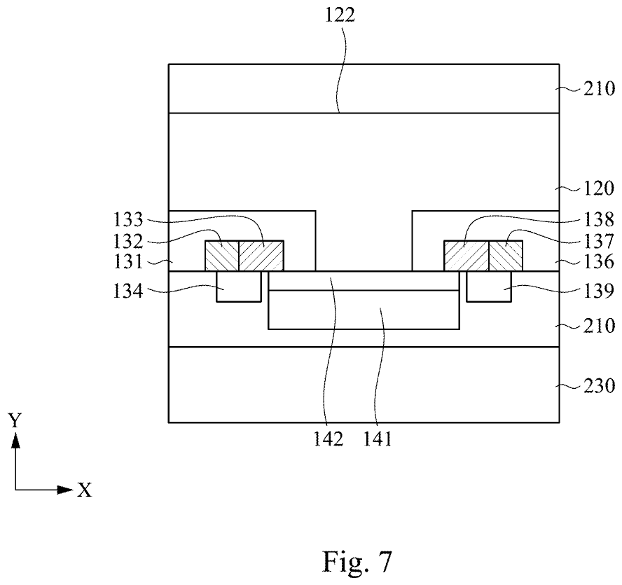

As shown in FIGS. 6 and 7, a transfer substrate 230 is connected and fixed to the first side 121 of the epitaxial layer 120 by the adhesive layer 220, and the epitaxial layer 120 is flipped by the transfer substrate 230. In this embodiment, the first side 121 of the epitaxial layer 120 includes the well 131, the doped region 132, the doped region 133, the electrode 134, the gate structure including the conductive layer 141 and the oxide layer 142, the well 136, the doping region 133, the doped region 137, the doped region 138 and the electrode 139. In some embodiments, the transfer substrate 230 is used to temporarily fix the semiconductor substrate 210, the epitaxial layer 120 and one or more elements/structures on the epitaxial layer 120. In the subsequent process, the transfer substrate 230 can be disconnected from the epitaxial layer 120 by removing the adhesive layer 220. With the arrangement of the transfer substrate 230, further semiconductor processes can be easily performed on the second side 122 of the semiconductor epitaxial layer 120.

In one or more embodiments of the present disclosure, as example but not limited thereto, the transfer substrate 230 includes a sapphire substrate.

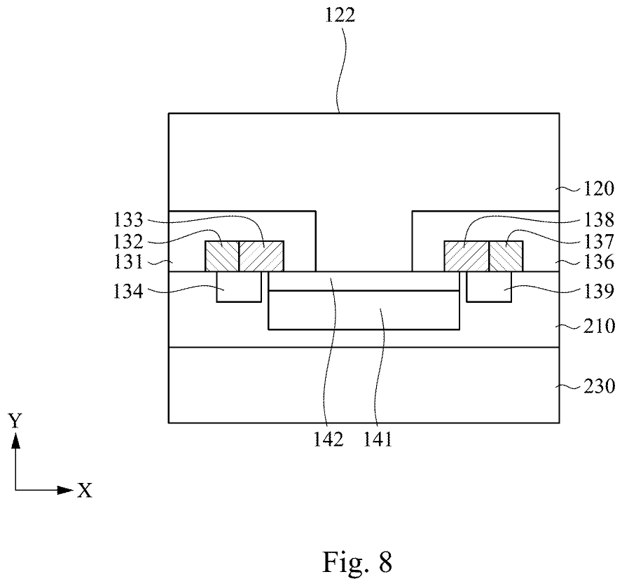

In FIG. 8, the semiconductor substrate 210 is removed. In other words, the semiconductor substrate 210 can be regarded as a temporary substrate. After the semiconductor substrate 210 is used to depositively form the epitaxial layer 120, the temporary semiconductor substrate 210 can be removed, and the second side 122 of the epitaxial layer 120 is exposed.

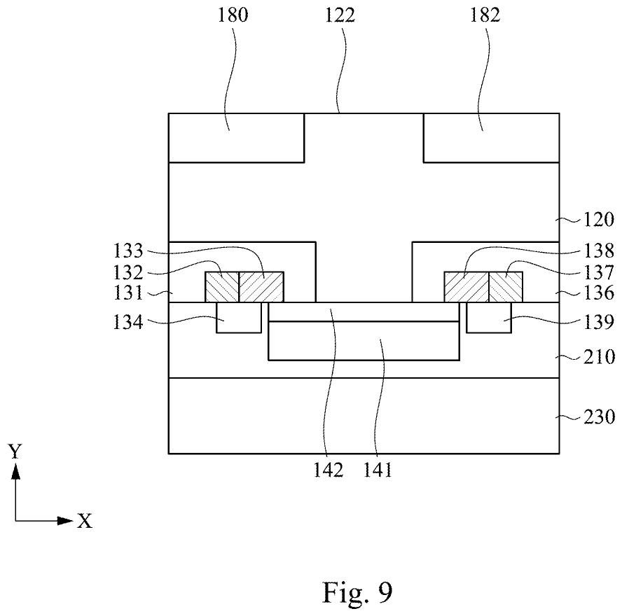

Following FIG. 8, in FIG. 9, a semiconductor doping process is performed on the exposed second side 122 of the epitaxial layer 120 to form semiconductor doped wells 180 and 182 extending from the second side 122 into the epitaxial layer 120. The well 180 and the well 182 have a second semiconductor type different from the first semiconductor type. In this embodiment, the wells 180 and 182 have p-type doping similar to the wells 131 and 136. As shown in FIG. 9, the well 180 and the well 182 are separated from each other in the direction X. The well 180 and the well 182 can be used to confine carriers from reaching the second side 122 through the epitaxial layer 120 which is not doped and does not have p⁺-doping. In this embodiment, the well 180 is formed in alignment with the well 131 and the well 182 is formed in alignment with the well 136.

A portion of the epitaxial layer 120 at the second side 122 does not have p-type doping and is exposed from the second side 122. In other words, the second side 122 of the epitaxial layer 120 further includes a connecting surface outside the well 180 and the well 182. In this embodiment, the connecting surface is located between the well 180 and the well 182. In one or more embodiments of the present disclosure, the epitaxial layer 120 exposed on the connecting surface of the second side 122 can be directly connected to the drain structure subsequently.

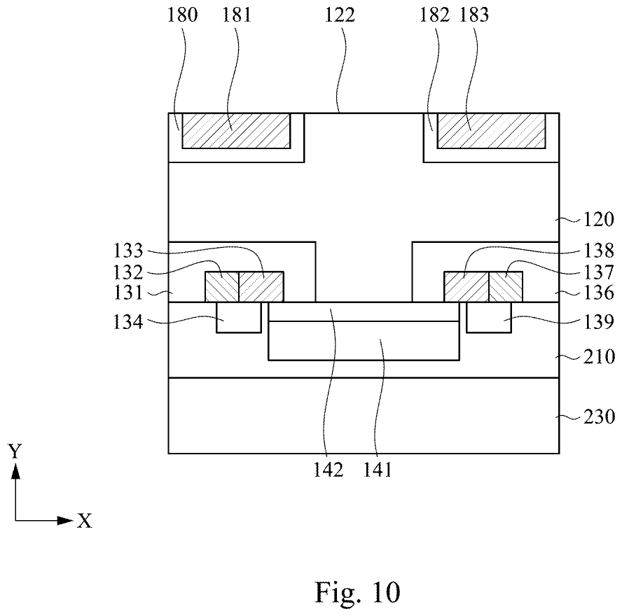

Following FIG. 9, in FIG. 10, a doped region 181 is formed in the well 180, and a doped region 183 is formed in the well 182. The doped region 181 and the doped region 183 have the second semiconductor type. In this embodiment, the doped region 181 and the doped region 183 have heavily n⁺-doping. Accordingly, the well 180 and the doped region 181 form a PN junction on the second side 122 of the epitaxial layer 120, and the well 182 and the doped region 183 form another PN junction on the second side 122 of the epitaxial layer 120. Forming the PN junctions on the back side (i.e., second side 122) of the epitaxial layer 120 can block unintended current paths without occupying additional space on the front side (i.e., first side 121) of the epitaxial layer 120.

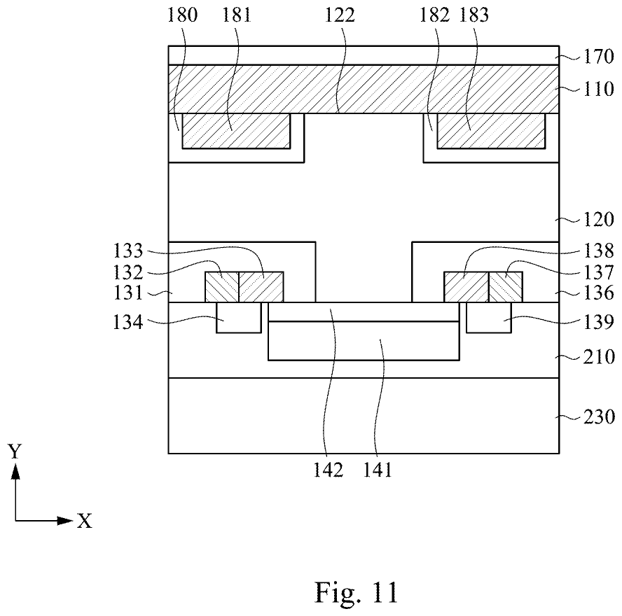

In FIG. 11, the substrate 110 is formed to cover the second side 122 of the epitaxial layer 120 and the electrodes 170 are formed on the substrate 110. The substrate 110 is of the same first semiconductor type as the doped regions 133 and 138 and has a heavily doping concentration. The electrode 170 may be a layer of conductive material. For example, the electrode 170 may be a metal layer formed on the substrate 110. In this embodiment, the substrate 110 has a heavily n⁺-doping. The substrate 110 is in contact with the second side 122 of the epitaxial layer 120 outside the well 180 and the well 182 to be in direct contact with the connecting surface of the epitaxial layer 120 between the well 180 and the well 182. The substrate 110 can be used as the drain structure of the transistor.

Therefore, the doped region 133, the well 131 and the substrate 110 form an n-p-n structure, and the p-doped well 131 is connected to the oxide layer 142 and the conductive layer 141 of the gate structure to form a vertical transistor. The doped region 133 is used as a source and is connected to the source electrode 134. The substrate 110 is used as a drain and is connected to the drain electrode 170. By applying a bias voltage through the conductive layer 141, an on/off switching of a channel of the vertical transistor can be controlled.

On the other hand, the doped region 138, the well 136 and the substrate 110 also form an n-p-n structure, and the p-type doped well 136 is connected to the oxide layer 142 and the conductive layer 141 of the gate structure and form another vertical transistor. The doped region 138 is used as a source and is connected to the source electrode 139. The substrate 110 is used as a drain and is connected to the drain electrode 170. By applying a bias voltage through the conductive layer 141, an on/off switching of a channel of another vertical transistor can be controlled.

It can be noted that in the process of forming the well 180, the well 182, the doped region 181 and the doped region 183 and in the processes of disposing the substrate 110 and the electrode 170, the transfer substrate 230 always remains and is connected the semiconductor epitaxial layer 120 through the adhesive layer 220 in FIGS. 9 and 10. In other words, the transfer substrate 230 and the adhesive layer 220 should be selected to withstand the high temperature in the process of forming the well 180, the well 182, the doped region 181 and the doped region 183 and in the process of disposing the substrate 110 and the electrode 170.

For example, in the process of forming the well 180, the well 182, the doped region 181 and the doped region 183, the process may include doping the semiconductor epitaxial layer 120 with a dopant and performing an annealing process to activate the implanted particles in the doped region 181 and the doped region 183. During the annealing process, the adhesive layer 220 and the transfer substrate 230 are disposed under a temperature over 1000° C., and the adhesive layer 220 and the transfer substrate 230 are made of materials that can withstand temperatures in excess of 1000° C. In some embodiments, the material of the semiconductor epitaxial layer 120 is silicon carbide, and the implanted ions doped into the semiconductor epitaxial layer 120 may be activated/annealed at an operating temperature of more than 1700° C., in which case the adhesive layer 220 and the transfer substrate 230 are made of a material being capable of withstand a temperature of more than 1700° C. In some embodiments, the transfer substrate 230 includes a sapphire substrate.

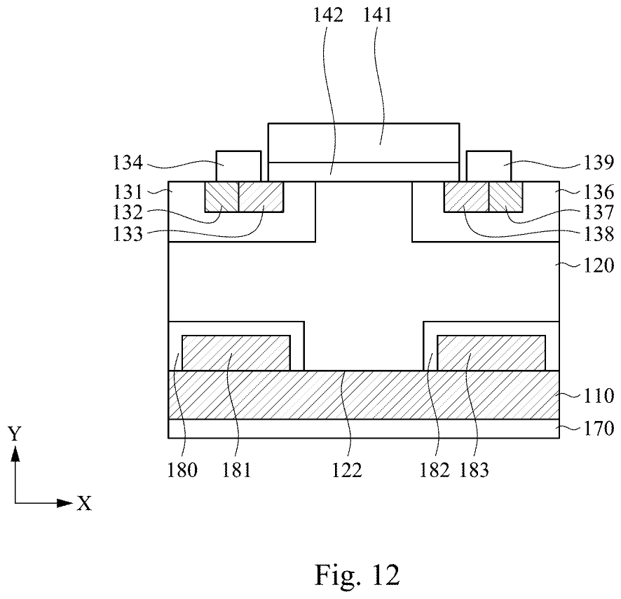

Following FIG. 11, in FIG. 12, the epitaxial layer 120 and the substrate 110 are flipped. In one or more embodiments of the present disclosure, the epitaxial layer 120 and the substrate 110 can be easily flipped by the transfer substrate 230, so that the first side 121 of the epitaxial layer 120 faces upward and the second side 122 of the epitaxial layer 120 faces downward.

In the schematic cross-section view as illustrated in FIG. 12, the adhesive layer 220 and the transfer substrate 230 are removed to form a semiconductor structure 100. The formed semiconductor structure 100 includes a vertical transistor formed by the doped region 133, the well 131 and the substrate 110 and a vertical transistor formed by the doped region 138, the well 136 and the substrate 110. In the semiconductor structure 100 as shown in FIG. 12, by forming wells (e.g., well 180, well 182) and doped regions (e.g., doped regions 181, 183) on the second side 122 of the epitaxial layer 120, unexpected leakage current can be blocked, and the wells and doped regions formed on the second side 122 of the epitaxial layer 120 would not occupy too much additional area on the first side 121 of the epitaxial layer 120.

In one or more embodiments of the present disclosure, the electrode 134 and the electrode 139 of the sources can be formed after the transfer substrate 230 is removed.

FIGS. 2-12 illustrate an embodiment of forming the semiconductor structure 100 of the present disclosure. In one embodiment of the present disclosure, the semiconductor structure 100 can form another type of drain structure on the second side 122 of the epitaxial layer 120.

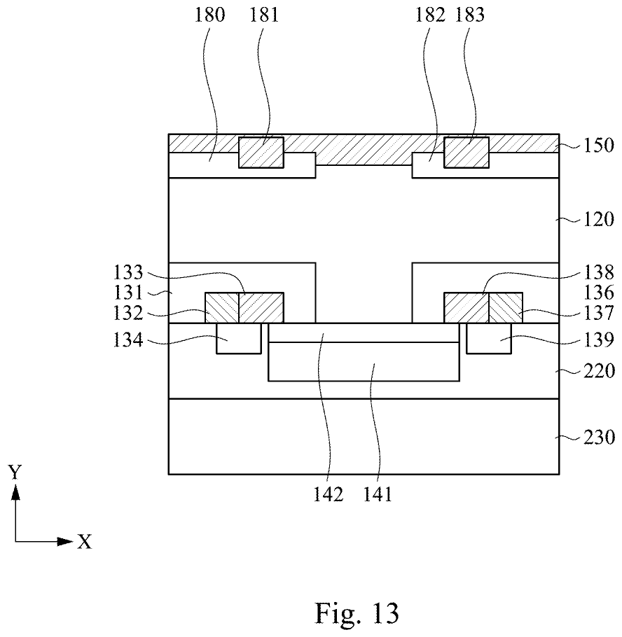

Reference is made to FIGS. 13-16. FIGS. 13-16 illustrate a plurality of schematic cross-sectional views of a plurality of intermediate operations forming a semiconductor structure 100 according to an embodiment of the present disclosure. For the purpose of simplicity of description, similar reference labels are used for similar elements and regions.

Reference is made to FIGS. 2-9. In FIGS. 2 to 9, wells (i.e., the well 131 and the well 136), source doped regions (i.e., the doped region 133 and the well 136) and a gate structure including the conductive layer 141 and the oxide layer 142 are formed on the first side 121 of the epitaxial layer 120. Subsequently, the first side 121 of the epitaxial layer 120 is fixed on the transfer substrate 230 through the adhesive layer 220, and the substrate 210 on the second side 122 of the epitaxial layer 120 is removed. In FIG. 9, the wells 180 and 182 having a second semiconductor type (e.g., p-type doping) are formed on the second side 122 of the epitaxial layer 120, and the wells 180 and 182 are separated from each other in the direction X. Similar processes are not repeated in detail.

In an embodiment of the present disclosure, following FIG. 9 and referring to FIG. 13, the entire surface of the second side 122 of the epitaxial layer 120 can be doped with the first semiconductor type after the well 180 and the well 182 of the second semiconductor type are formed. In this embodiment, performing n-type doping on the entire second side 122 of the epitaxial layer 120 includes performing n-type doping on the well 180, the well 182, and the connecting surface of the second side 122 between the well 180 and the well 182. Accordingly, the doped regions 181 and 183 are formed and respectively extend into the well 180 and the well 182, and the additional doped region 150 is formed and extends from the second side 122 of the epitaxial layer 120 into the epitaxial layer 120.

In the embodiment shown in FIG. 13, the formed doped region 150 extends between well 180 and well 182, which are separated from each other in direction X. The doped region 150, the doped region 181 and the doped region 183 have a first semiconductor type different from the second semiconductor type of well 180 and well 182. In this embodiment, the doped region 150, the doped region 181 and the doped region 183 have heavily n⁺-doping.

In one or more embodiments of the present disclosure, the doped region 150, the doped region 181 and the doped region 183 may have the same or similar doping concentration. In other words, in some embodiments, the doped region 150, the doped region 181 and the doped region 183 may be regarded as the same doped region. To illustrate that the doped region 181 and the doped region 183 respectively extend to the well 180 and the well 182, the doped region 150, the doped region 181 and the doped region 183 are shown as different blocks in FIG. 13, but not limit to the aspect of this disclosure.

In the embodiment shown in FIG. 13, the well 180 and the doped region 181 form a PN junction on the second side 122 of the epitaxial layer 120, and the PN junction is capable of blocking unintended carrier migration. The well 182 and the doped region 183 form another PN junction on the second side 122 of the epitaxial layer 120 and the PN junction formed by the well 182 and the doped region 183 can block unintended carrier migration. These PN junctions formed on the second side 122 of the epitaxial layer 120 do not occupy additional area of the first side 121 of the epitaxial layer 120.

In some embodiments, the doped region 150 extends between well 180 and the well 182 and has a heavily n⁺-doping. The doped region 150 can be used as a part of the drain structure.

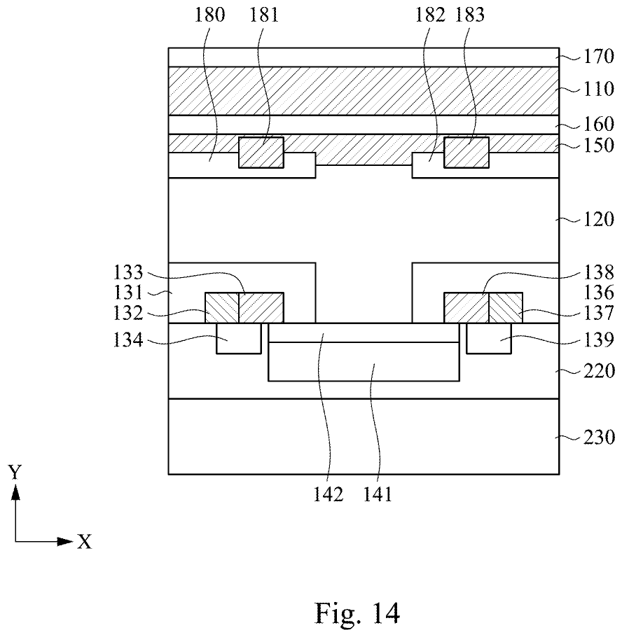

Reference is made to FIG. 14. As shown in the schematic cross-sectional view shown in FIG. 14, in this embodiment, the substrate 110 having a heavily n⁺-doping is bonded to the doped region 150 through the conductive layer 160, so that the substrate 110 is connected to the well 180, the well 182 and the connecting surface of the second side 122 outside the well 180 and the well 182 through the conductive layer 160. The substrate 110 can also be considered as part of the drain structure. Therefore, the substrate 110 and the doped region 150 can be used as the drain structure of the vertical transistor. The electrode 170 covers the substrate 110 and serves as a drain electrode.

In one or more embodiments of the present disclosure, the conductive layer 160 and the electrode 170 are, for example, metal layers. As an example and but not limit to the present disclosure, in some embodiments, the material of the conductive layer 160 includes a deposited layer of titanium (Ti)/nickel (Ni)/silver (Ag).

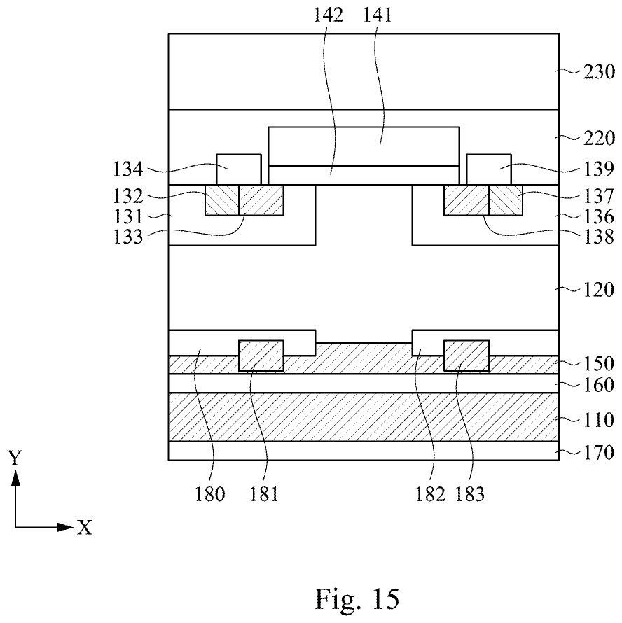

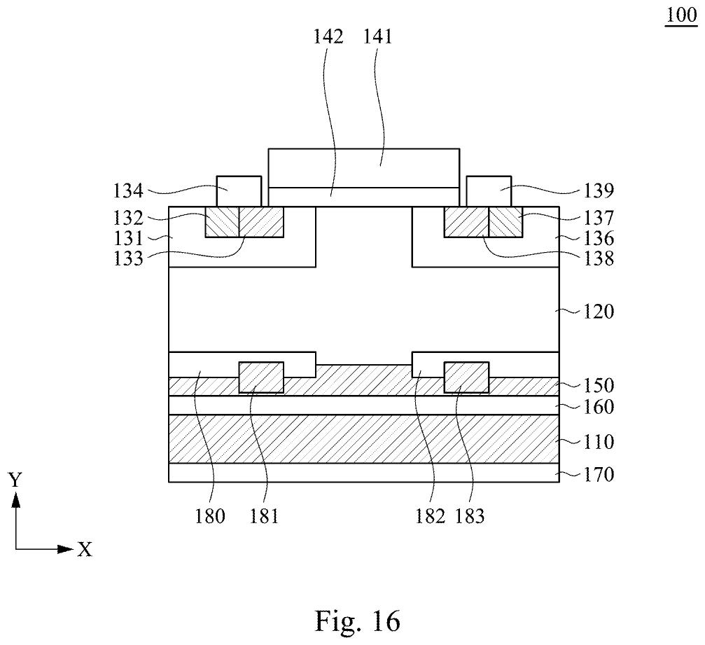

In FIG. 15, the epitaxial layer 120 and the substrate 110 are flipped by the transfer substrate 230. Then, in FIG. 16, the adhesive layer 220 and the transfer substrate 230 are removed to form the semiconductor structure 100.

The semiconductor structure 100 shown in FIG. 16 may include two vertical transistor structures. For example, the doped region 133, the well 131, the doped region 150 and the substrate 110 can form an n-p-n junction structure, and the well 131 with p-type doping is connected to the oxide layer 142 and the conductive layer 141, which are used as the gate structure. The doped region 133 can be used serve as the source of the vertical transistor and is connected to the source electrode 134. The doped region 150 and the substrate 110 can be used as the drain of the vertical transistor and are connected to the drain electrode 170. Similarly, the doped region 138, the well 136, the doped region 150 and the substrate 110 can form an n-p-n junction structure, and the well 136 with p-type doping is connected to the gate structure including the oxide layer 142 and the conductive layer 141. The doped region 138 can be used as the source of the vertical transistor and is connected to the source electrode 139. The doped region 150 and the substrate 110 can be used as the drain of the vertical transistor and are connected to the drain electrode 170. Therefore, the operating voltage can be applied to the gate structure through the conductive layer 141 to control the on/off switching of the vertical transistor by the gate structure.

In the semiconductor structure 100 shown in FIG. 16, the doped region 150 extending from the second side 122 into the epitaxial layer 120 can be formed to decrease a distance between a top surface of the doped region 150 and the oxide layers 142 on the first side 212, and it reduces the equivalent on-resistance of the vertical transistors. On the other hand, the well 180 and the well 182 surround doped region 150. The PN junction formed by the well 180 and the doped region 181 and the PN junction formed by the well 182 and the doped region 183 can restrict the flow of carriers such that the carriers move to the doped region 150.

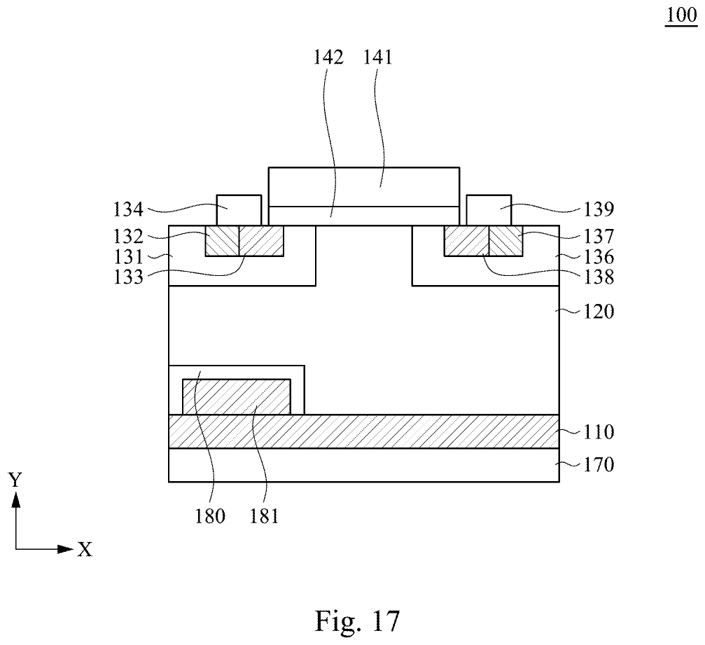

Reference is made to FIG. 12 again and FIGS. 17-19 to illustrate semiconductor structure according to one or more embodiments of the present disclosure.

FIG. 17 illustrates a schematic cross-sectional view of a semiconductor structure according to one or more embodiments of the present disclosure. Different from the embodiment shown in FIG. 12, in the semiconductor structure 100 of FIG. 17, the second side 122 of the epitaxial layer 120 includes only one set of the well 180 and the doped regions 181 aligned with the wells 131. The PN junction formed by the well 180 and the doped region 181 can still be used to block a part of the carrier flow. Accordingly, the epitaxial layer 120 retains a large area of connecting surface on the second side 122 outside the well 180 for the substrate 110 to be connected, and the overall withstand voltage resistance can still be improved through the well 180 and the doped region 181.

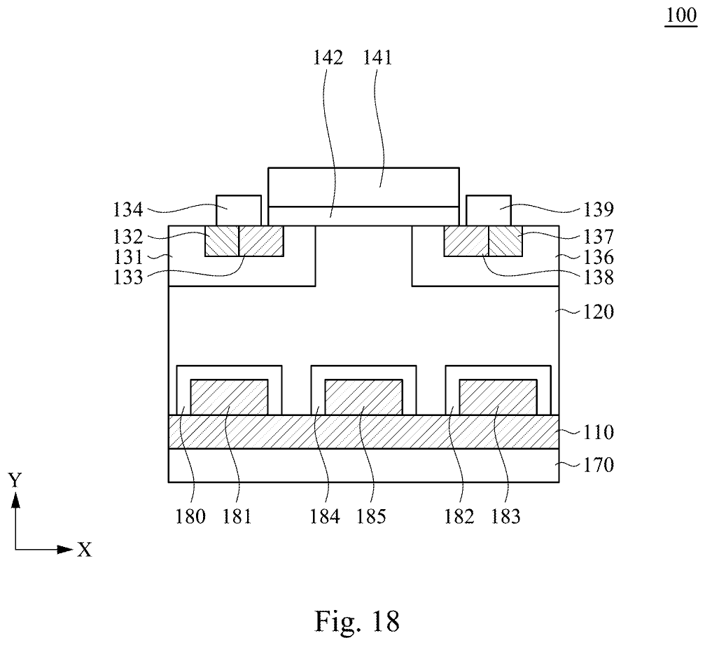

FIG. 18 illustrates a schematic cross-sectional view of a semiconductor structure according to one or more embodiments of the present disclosure. Different from the embodiment shown in FIG. 12, in the semiconductor structure 100 of FIG. 17, the well 180, the doped region 181, the well 182 and the doped region 183 are reduced in size, and a well 184 and a doped region 185 are further disposed between the well 180 and the well 182. The well 184 has the same second semiconductor type (e.g., p-type doping) as the well 180 and the well 182. The doped region 185 is formed in well 184 and has the same first semiconductor type (e.g., heavily n⁺-doping) as the doped region 181 and the doped region 183. Therefore, the well 184 and the doped region 185 can form another PN junction on the second side 122 for blocking leakage current. Furthermore, as shown in FIG. 18, the well 184 is offset in direction X from the well 180 and the well 182.

In one or more embodiments of the present disclosure, the well 184 may be formed in the same fabrication process that forms the well 180 and the well 182, and the doped region 185 may be formed in the same fabrication process that forms doped regions 181 and 183.

In the embodiment as illustrated in FIG. 17, the epitaxial layer 120 includes a plurality of connecting surfaces between the well 180, the well 182 and the well 184 on the second side 122. These connecting surfaces are separated from each other in the direction X and are offset from the center of the oxide layer 142 and the conductive layer 141 of the gate structure.

As shown in the embodiments illustrated in FIGS. 17 and 18, one or more sets of PN junctions formed by wells and doped regions cab be provided on the second side 122 of the epitaxial layer 120, and these PN junctions are able to block parts of the unintended flow of carriers in the epitaxial layer 120 to increase the withstand voltage resistance and avoid leakage current.

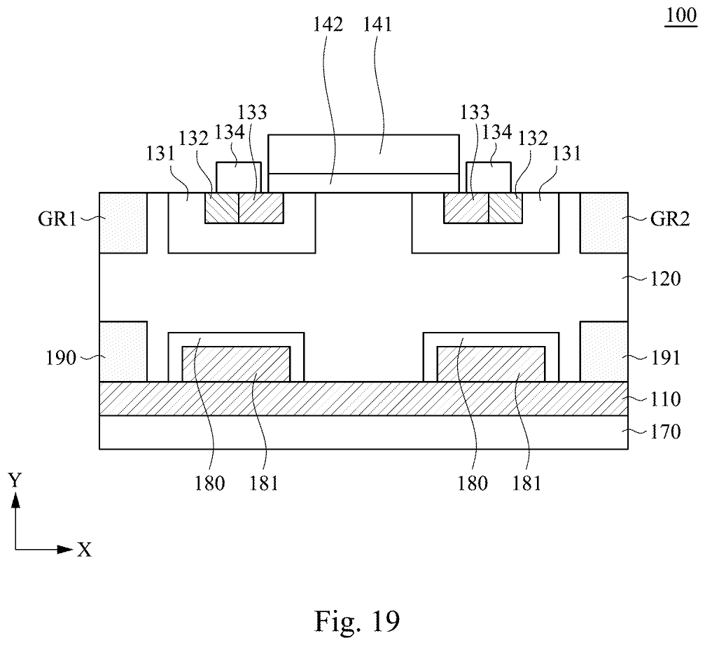

FIG. 19 illustrates a schematic cross-sectional view of the semiconductor structure 100 according to one or more embodiments of the present disclosure.

Reference is made to FIG. 12 and FIG. 19. Different from the embodiment shown in FIG. 12, in the semiconductor structure 100 of FIG. 19, a guard ring structure is further provided on the first side 121 of the epitaxial layer 120. As schematically shown in FIG. 19, the guard ring structure includes a guard ring well GR1 and a guard ring well GR2. The guard ring well GR1 and the guard ring well GR2 surround the well 131 and the well 136 on the first side 121 of the epitaxial layer 120 in the direction X. As shown in FIG. 19, in some embodiments, the guard ring well GR1 and the guard ring well GR2 are of the same second semiconductor type as wells 131 and 136. In this embodiment, the guard ring well GR1 and the guard ring well GR2 have p-type doping. The guard ring well GR1 and the guard ring well GR2 form a PN junction with the epitaxial layer 120 to avoid leakage current in the horizontal direction X.

Furthermore, in the semiconductor structure 100 of FIG. 19 according to the positions of the guard ring well GR1 and the guard ring well GR2 on the first side 121 of the epitaxial layer 120, a doped well 190 and a doped well 191 are formed on the second side 122, wherein the well 190 is aligned with the guard ring well GR1 in the direction Y, and the well 191 is aligned with the guard ring well GR2 in the direction Y, so that the well 190 and the well 191 surround the well 180 and the well 182.

The well 190 and the well 191 may be of the same second semiconductor type as the well 131 and the well 136. In this embodiment, the well 190 and the well 191 have p-type doping. The well 190 and the epitaxial layer 120 form a PN junction. The well 191 and the epitaxial layer 120 form another PN junction. The PN junctions formed by the wells 190, 191 and the epitaxial layer 120 can avoid unintended leakage current in the horizontal direction X of the second side 122 of the epitaxial layer 120.

In some embodiments of the present disclosure, the guard ring well GR1 and the guard ring well GR2 of the guard ring structure may be formed in the same manufacturing process in which the well 131 and the well 136 are formed. The well 190 and the well 191 may be formed in the same fabrication process that forms the well 180 and the well 182.

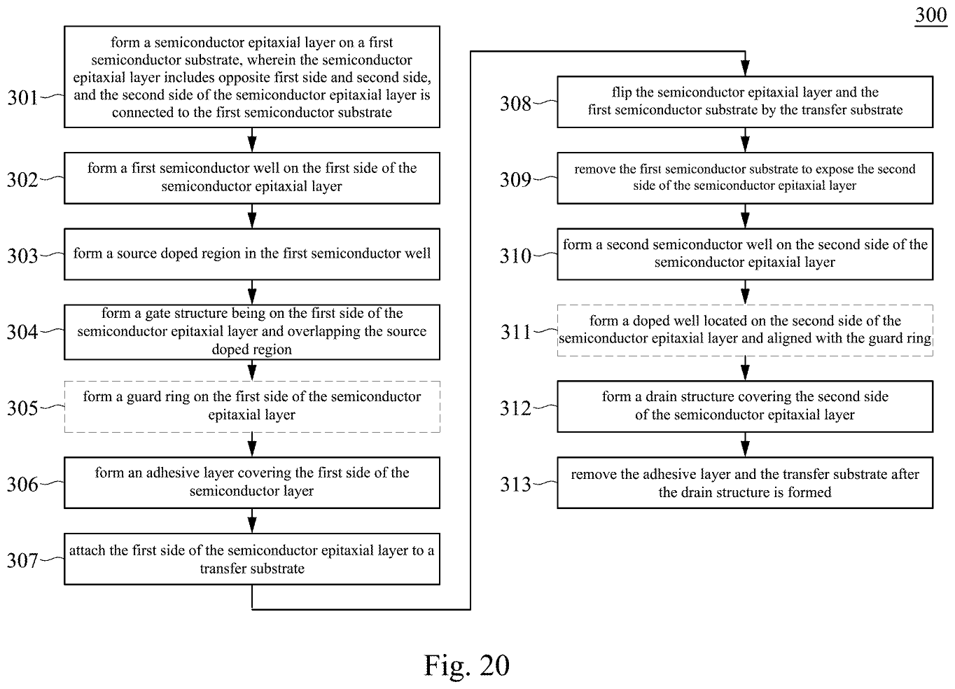

Reference is made to FIG. 20 to summarize method of forming semiconductor structures according to one or more embodiments of the present disclosure. FIG. 20 illustrates a flowchart of a method 300 of forming a semiconductor structure 100 according to one or more embodiments of the present disclosure.

In an embodiment of the present disclosure, please refer to FIG. 20 and FIGS. 2-16.

Reference is made to FIG. 2 and FIG. 3. In operation 301, a semiconductor epitaxial layer 120 is formed on a first semiconductor substrate 210, wherein the semiconductor epitaxial layer 120 includes opposite first side 121 and second side 122, the second side 122 of the semiconductor epitaxial layer 120 is connected to the first semiconductor substrate 210.

Reference is made to FIG. 4. In operation 302, first semiconductor wells 131 and 136 are formed on the first side 121 of the semiconductor epitaxial layer 120. Then, in operation 303, the source doped regions 133 and 138 are respectively formed in the first semiconductor wells 131 and the 136.

Reference is made to FIG. 5. In operation 304, a gate structure is formed on the first side of the semiconductor epitaxial layer and overlaps source doped regions 133 and 138, wherein the gate structure includes an oxide layer 142 and a conductive layer 141.

Reference is made to FIG. 19. In an option operation 305, a guard ring can be formed on the first side 121 of the semiconductor epitaxial layer 120, wherein the guard ring includes a guard ring well GR1 and a guard ring well GR2 formed on the first side 121 of the epitaxial layer. In some embodiments, the guard ring well GR1 and the guard ring well GR2 may be formed in the same operation 302 that forms the well 131 and the well 136.

Reference is made to FIG. 6. In operation 306, an adhesive layer 220 is formed to cover the first side 121 of the semiconductor epitaxial layer 120. Then, in operation 307, the first side 121 of the semiconductor epitaxial layer 120 is attached to a transfer substrate 230 by the adhesive layer 220.

Reference is made to FIG. 7. In operation 308, the semiconductor epitaxial layer 120 and the first semiconductor substrate 210 are flipped by the transfer substrate 230.

Reference is made to FIG. 8. In operation 309, the first semiconductor substrate 210 is removed to expose the second side 122 of the semiconductor epitaxial layer 120.

Reference is made to FIG. 10. In operation 310, second semiconductor wells 180 and 182 are formed on the second side 122 of the semiconductor epitaxial layer 120.

Reference is made to FIG. 19. In an option operation 311, doped wells 190 and 191 formed on the second side 122 of the semiconductor epitaxial layer 120 and respectively aligned with the guard ring wells GR1 and GR2 of the guard ring. In some embodiments, operations 310 and 311 can be performed in the same operation.

Reference is made to FIG. 11 or FIGS. 13-14. In operation 312, a drain structure covering the second side 122 of the semiconductor epitaxial layer 120 is formed. For the embodiment as illustrated in FIG. 11, the substrate 110 of the drain structure is connected to the second side 122 of the epitaxial layer 120. For the embodiment as illustrated in FIG. 13, a doped region 150 is formed on the entire surface of the second side 122 of the epitaxial layer 120, and the substrate 110 is bonded to the doped region 150 through a conductive layer 160.

Reference is made to FIG. 12 or FIGS. 15-16. In operation 313, the adhesive layer 220 and the transfer substrate 230 are removed after the drain structure is formed, and the semiconductor structure 100 is formed.

In summary, in one or more embodiments of the present disclosure, it can be applied to the back side of the epitaxial layer of the semiconductor structure, and a withstand voltage structure is arranged on the back side of the epitaxial layer to avoid leakage. In addition, in the semiconductor process for forming the semiconductor structure, by arranging the transfer substrate, the semiconductor process can be flexibly performed on the front side and the back side of the semiconductor epitaxial layer to form the structure to be required, so that the structure to be required can be formed without occupying additional device area. Additional doped regions for the semiconductor epitaxial layer in the vertical transistor structure increase the withstand voltage to avoid the generation of unintended leakage current.

Although the embodiments of the present disclosure have been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the embodiments of the present disclosure without departing from the scope or spirit of the present disclosure. In view of the foregoing, it is intended that the present disclosure cover modifications and variations of this disclosure provided they fall within the scope of the following claims.

What is claimed is:

1. A semiconductor structure comprising:
a semiconductor epitaxial layer comprising a first side and a second side opposite to the first side;
a first semiconductor well located on the first side of the semiconductor epitaxial layer;
a second semiconductor well located on the second side of the semiconductor epitaxial layer;
a source doped region located in the first semiconductor well;
a gate structure located on the first side of the semiconductor epitaxial layer and overlapping the first semiconductor well and the source doped region; and
a drain structure comprising a semiconductor substrate, wherein the second side of the semiconductor epitaxial layer comprises a connecting surface located on the second side of the semiconductor epitaxial layer and outside the second semiconductor well, and the connecting surface is connected to the semiconductor substrate.

2. The semiconductor structure of claim 1, wherein the drain structure further comprises:
a drain doped region extending from the second side of the semiconductor epitaxial layer into the semiconductor epitaxial layer; and
a conductive layer connecting the drain doped region to the semiconductor substrate.

3. The semiconductor structure of claim 2, wherein the drain doped region extends into the second semiconductor well and extends to the second side of the semiconductor epitaxial layer outside the second semiconductor well.

4. The semiconductor structure of claim 1, further comprising:
a source electrode located on the first side of the semiconductor epitaxial layer, overlapping the source doped region and separated from the gate structure; and
a drain electrode located below the semiconductor substrate of the drain structure, wherein the semiconductor substrate is located between the drain electrode and the semiconductor epitaxial layer.

5. The semiconductor structure of claim 1, further comprising:
a third semiconductor well located on the first side of the semiconductor epitaxial layer; and
another source doped region located in the third semiconductor well and covered by the gate structure.

6. The semiconductor structure of claim 1, further comprising:
a guard ring well extending from the first side of the semiconductor epitaxial layer into the semiconductor epitaxial layer and surrounding the first semiconductor well; and
a third semiconductor well extending from the second side of the semiconductor epitaxial layer into the semiconductor epitaxial layer and surrounding the second semiconductor well.

7. A semiconductor structure comprising:
a semiconductor epitaxial layer comprising a first side and a second side opposite to the first side;
a first semiconductor well located on the first side of the semiconductor epitaxial layer;
a second semiconductor well located on the second side of the semiconductor epitaxial layer and aligned with the first semiconductor well;
a source doped region located in the first semiconductor well;
a gate structure located at the first side of the semiconductor epitaxial layer and overlapping the first semiconductor well and the source doped region; and
a drain structure comprising a semiconductor substrate, wherein the second side of the semiconductor epitaxial layer comprises a connecting surface outside the second semiconductor well, the connecting surface is connected to the semiconductor substrate, wherein each of the source doped region, the semiconductor epitaxial layer and the semiconductor substrate has a first semiconductor type, each of the first semiconductor well and the second semiconductor well has a second semiconductor type different from the first semiconductor type.

8. The semiconductor structure of claim 7, wherein the drain structure further comprises:
a drain doped region having a first semiconductor type and extending from the second side of the semiconductor epitaxial layer into the semiconductor epitaxial layer; and
a conductive layer connecting the drain doped region to the semiconductor substrate.

9. The semiconductor structure of claim 8, wherein the drain doped region extends into the second semiconductor well.

10. The semiconductor structure of claim 7, further comprising:
a source electrode located on the first side of the semiconductor epitaxial layer, overlapping the source doped region and separated from the gate structure; and
a drain electrode located below the semiconductor substrate of the drain structure, wherein the semiconductor substrate is located between the drain electrode and the semiconductor epitaxial layer.

11. The semiconductor structure of claim 7, further comprising:
a guard ring well extending from the first side of the semiconductor epitaxial layer into the semiconductor epitaxial layer and surrounding the first semiconductor well; and
a third semiconductor well extending from the second side of the semiconductor epitaxial layer into the semiconductor epitaxial layer and surrounding the second semiconductor well.

12. The semiconductor structure of claim 7, wherein the gate structure comprising:
an oxide layer located on the first side of the semiconductor epitaxial layer and overlapping the source doped region; and
a gate electrode located on the oxide layer.

13. The semiconductor structure of claim 7, wherein the semiconductor substrate is a silicon carbide substrate.

14. A method of forming a semiconductor structure comprising:
forming a semiconductor epitaxial layer on a first semiconductor substrate, wherein the semiconductor epitaxial layer comprises a first side and a second side opposite to the first side, the second side of the semiconductor epitaxial layer is connected to the first semiconductor substrate;
forming a first semiconductor well on the first side of the semiconductor epitaxial layer;
forming a source doped region in the first semiconductor well;
forming a gate structure located on the first side of the semiconductor epitaxial layer and overlapping the first semiconductor well and the source doped region;
forming an adhesive layer covering the first side of the semiconductor epitaxial layer;
fixing the first side of the semiconductor epitaxial layer on a transfer substrate;
flipping the semiconductor epitaxial layer and the first semiconductor substrate by the transfer substrate;
removing the first semiconductor substrate to expose the second side of the semiconductor epitaxial layer;
forming a second semiconductor well on the second side of the semiconductor epitaxial layer;
forming a drain structure covering the second side of the semiconductor epitaxial layer; and
after the drain structure is formed, removing the adhesive layer and the transfer substrate.

15. The method of claim 14, wherein forming the drain structure comprising:
connecting a second semiconductor substrate to the second side of the semiconductor epitaxial layer; and
forming a drain electrode below the second semiconductor substrate, wherein the second semiconductor substrate is located between the semiconductor epitaxial layer and the drain electrode.

16. The method of claim 14, wherein forming the drain structure comprises:
after the second semiconductor well is formed, forming a drain doped region extending from the second side of the semiconductor epitaxial layer into the semiconductor epitaxial layer and the second semiconductor well; and
connecting a second semiconductor substrate to the drain doped region by a conductive layer.

17. The method of claim 14, wherein the second semiconductor well is formed to be aligned with the first semiconductor well.

18. The method of claim 14, wherein forming the gate structure comprising:
before the adhesive layer is formed or the transfer substrate is removed, forming an oxide layer overlapping the first side of the semiconductor epitaxial layer; and
forming a conductive layer over the oxide layer.

19. The method of claim 14, further comprising:
before the adhesive layer is formed or the transfer substrate is removed, forming a source electrode separated from the gate structure and overlapping the source doped region.

20. The method of claim 14, wherein the first semiconductor substrate is a silicon carbide substrate, and the transfer substrate is a sapphire substrate.
